(19) United States
(12) Patent Application Publication
(10) Pub. No.: US 2026/0033245 A1
(43) Pub. Date: Jan. 29, 2026

(54) MULTILAYER PIEZOELECTRIC ELEMENT

(71) Applicant: TAIYO YUDEN CO., LTD., Chuo-ku, Tokyo (JP)

(72) Inventors: Ryo ITO, Takasaki-shi (JP); Takayuki GOTO, Takasaki-shi (JP)

(21) Appl. No.: 18/998,048

(22) PCT Filed: Jul. 10, 2023
(86) PCT No.: PCT/JP2023/025384

§ 371 Date: Jan. 23, 2025

(30) Foreign Application Priority Data
Aug. 1, 2022 (JP) 2022-122886

(51) Int. Cl. H10N 30/853; H10N 30/053; H10N 30/067; H10N 30/097; H10N 30/50; H10N 30/87

(52) U.S. Cl. CPC H10N 30/8542; H10N 30/053; H10N 30/067; H10N 30/097; H10N 30/50; H10N 30/871; H10N 30/877

(57) ABSTRACT

A multilayer piezoelectric element includes: (i) multiple piezoelectric ceramic layers, wherein: a primary component constitutes a perovskite structure of an alkali niobate; at least one of calcium, strontium, and barium, and silver, are contained; 0.1-2.0 mol of lithium, and 1.5-4.0 mol of silicon, per 100 mol of the primary component, are contained in a manner that a ratio of Li/Si becomes 0.025 or higher but under 0.40; and as measured with an X-ray diffraction measurement, a strongest diffraction line intensity (Iₘₐₓ) at 10.00°≤2θ≤50.00°, a strongest diffraction line intensity (I_{L2S}) at 26.50°≤2θ≤27.50°, and an average value of diffraction line intensity (IBG) at 27.50°≤2θ≤29.00° satisfy a relationship R₁=(I_{L2S}−I_{BG})/(Iₘₐₓ−I_{BG})×100≥0.20; and (ii) internal electrodes that are placed between the multiple piezoelectric ceramic layers, and formed by a metal whose silver content is 80% by mass or higher.

### TECHNICAL FIELD

The present invention relates to a multilayer piezoelectric element.

### BACKGROUND ART

A piezoelectric element is an electronic component having a structure where a ceramic with piezoelectricity (piezoelectric ceramic) is sandwiched between a pair of electrodes. Here, “piezoelectricity” refers to a property of a material to be able to convert electrical energy into mechanical energy and vice versa.

By utilizing the aforementioned property of the piezoelectric ceramic to convert the voltage impressed between the pair of electrodes into pressure, vibration, or other mechanical energy, the piezoelectric element can move another object or actuate itself. On the other hand, the piezoelectric element can also convert vibration, pressure, or other mechanical energy into electrical energy and allow the electrical energy to be taken out as voltage between the pair of electrodes.

Among the known structures of piezoelectric elements, besides the one where electrodes are formed only on the surface of a piezoelectric ceramic, is the so-called “multilayer piezoelectric element” comprising multiple piezoelectric ceramic layers and internal electrode layers stacked together alternately. Multilayer piezoelectric elements allow large displacements to be obtained in the stacking direction of their piezoelectric ceramic layers and thus can be utilized as actuators, and the like, for example. Multilayer piezoelectric elements are typically manufactured by simultaneously firing piezoelectric ceramic layers and internal electrode layers.

For the piezoelectric ceramics that constitute such piezoelectric elements, those whose primary component is lead zirconate titanate (Pb(Zr,Ti)O₃, PZT) or solid solution thereof are widely used. PZT-based piezoelectric ceramics have high Curie temperatures, which means that the piezoelectric elements comprising PZT-based piezoelectric ceramics can be used in high-temperature environments, as well. Also, PZT-based piezoelectric ceramics have high electromechanical coupling coefficients, which enables the piezoelectric elements comprising PZT-based piezoelectric ceramics to efficiently convert electrical energy into/from mechanical energy. In addition, PZT-based piezoelectric ceramics can be fired at temperatures lower than 1000° C. by selecting proper compositional makeups, which allows for reduction in the manufacturing costs of piezoelectric elements. In particular, the aforementioned multilayer piezoelectric elements generate considerable cost savings because low-melting-point materials having high content percentages of silver, i.e., low content percentages of platinum, palladium, and other expensive materials, can be used for the internal electrodes that are fired simultaneously with the piezoelectric ceramic.

However, PZT-based piezoelectric ceramics present a problem in that they contain lead which is a harmful substance, and there is a demand for lead-free piezoelectric ceramic compositions as alternatives to PZT-based piezoelectric ceramics.

To date, lead-free piezoelectric ceramics having various compositional makeups, such as those based on alkali niobates ((Li,Na,K)NbO₃), bismuth sodium titanate ((Bi_{0.5}Na_{0.5})TiO₃, BNT), bismuth layered compounds, tungsten bronze, and the like, have been reported. Of these, alkali niobate-based piezoelectric ceramics having high Curie temperatures along with relatively large electromechanical coupling coefficients are drawing attention as alternatives to those PZT-based (Patent Literature 1).

Attempts have been made to reduce the manufacturing costs of multilayer piezoelectric elements by allowing for low-temperature firing of these alkali niobate-based piezoelectric ceramics so that they can be integrally fired with internal electrodes having high content percentages of silver.

For example, Patent Literature 2 discloses a technical concept of using an alkali niobate-based piezoelectric ceramic containing alkali earth metals and silver in its compositional makeup so that it can be integrally fired with internal electrodes whose silver content is 50% by mass or higher. Also, Cited Literature 2 reports a multilayer piezoelectric element having internal electrodes of Ag_{0.7}Pd_{0.3}, that exhibits high electrical resistivity while also demonstrating large displacement magnitudes when voltage is impressed.

In addition, Patent Literature 3 discloses a technical concept of using an alkali niobate-based piezoelectric ceramic containing silver and a specific amount of calcium or barium in its compositional makeup to form piezoelectric ceramic layers that contain sintered grains encapsulating silver-segregated regions of 10 nm or less in long diameter so that they can be integrally fired with internal electrodes formed by a metal whose silver content is 80% by mass or higher. Also, Cited Literature 3 reports a multilayer piezoelectric element comprising: piezoelectric ceramic layers obtained by adding 0.5% by mol of BaCO₃, 0.4% by mol of LiCO₃, 2.0% by mol of SiO₂, and 0.5% by mol of MnO to 100% by mol of an alkali niobate whose composition formula is Li_{0.064}Na_{0.52}K_{0.42}NbO₃; and internal electrodes of Ag_{0.9}Pd_{0.1}.

### Background Art Literature

### Patent Literature

Patent Literature 1: International Patent Laid-open No. 2007/094115
Patent Literature 2: Japanese Patent Laid-open No. 2017-163055
Patent Literature 3: Japanese Patent Laid-open No. 2021-158249

### SUMMARY OF THE INVENTION

### Problems to be Solved by the Invention

Patent Literature 2 mentions that the aforementioned alkali niobate-based piezoelectric ceramics may contain Li₂O and SiO₂ representing components that contribute to improvement of sintering property, and MnO representing a component that contributes to improvement of electrical resistance. However, it has come to light that, depending on the contents of these components, Li₃NbO₄ having conductivity and lithium manganate having a lower electrical resistivity compared to alkali niobates will be produced in large amounts in the piezoelectric ceramic, leading to a lowering of electrical insulating property while the element is in use and consequently a possible reduction in the service life of the element.

The multilayer piezoelectric element reported in Patent Literature 3 has a long service life and excellent piezoelectric properties. Still, there is a demand for multilayer piezoelectric elements that achieve a long service life and excellent piezoelectric properties at higher levels.

Accordingly, an object of the present invention is to provide a multilayer piezoelectric element whose constituents do not include lead, which can be manufactured based on integral firing with internal electrodes having a high content percentage of silver, and which can achieve both a long service life and excellent piezoelectric properties.

### Means for Solving the Problems

After conducting various studies to achieve the aforementioned object, the inventor of the present invention found that this object could be achieved by adding lithium and silicon to an alkali niobate at specific percentages so that the piezoelectric ceramic layers will contain a specified amount of Li₂SiO₃ when the multilayer piezoelectric element is manufactured.

To be specific, one aspect of the present invention to achieve the aforementioned object is a multilayer piezoelectric element comprising: multiple piezoelectric ceramic layers, wherein: the primary component is an alkali niobate having a perovskite structure; at least one type of alkali earth metal element selected from calcium, strontium, and barium, as well as silver, are contained; lithium by an amount corresponding to 0.1 mol or more but no more than 2.0 mol, and silicon by an amount corresponding to 1.5 mol or more but no more than 4.0 mol, relative to the primary component representing 100 mol, are contained in a manner that the ratio by mol of the lithium to the silicon, or Li/Si, becomes 0.025 or higher but under 0.40; and when an X-ray diffraction measurement is performed using Cu-Kα rays, wherein the strongest diffraction line intensity at 10.00°≤2θ≤50.00° is referred to as Iₘₐₓ, the strongest diffraction line intensity at 26.50°≤2θ≤27.500 is referred to as I_{L2S}, and the average value of diffraction line intensity at 27.50°≤2θ≤29.00° is referred to as IBG, R₁=(I_{L2S}−I_{BG})/(Iₘₐₓ−I_{BG})×100≥0.20 is satisfied; and internal electrode layers that are placed between the multiple piezoelectric ceramic layers; and formed by a metal whose silver content is 80% by mass or higher.

### Effects of the Invention

According to the present invention, a multilayer piezoelectric element whose constituents do not include lead, which can be manufactured based on integral firing with internal electrodes having a high content percentage of silver, and which achieves both a long service life and excellent piezoelectric properties, can be provided.

### BRIEF DESCRIPTION OF THE DRAWINGS

FIG. 1 is a cross-sectional view (section X-Z) showing the structure of a multilayer piezoelectric element pertaining to one aspect of the present invention.

FIG. 2 is a cross-sectional view (section Y-Z) showing the structure of a multilayer piezoelectric element pertaining to one aspect of the present invention.

FIG. 3 is a perspective view showing a unit lattice model of a perovskite structure.

### MODE FOR CARRYING OUT THE INVENTION

The constitutions and operations/effects of the present invention, together with the technical concepts, are explained below by referring to the drawings. It should be noted, however, that the operating mechanisms include estimations and whether they are correct or not does not limit the present invention.

### [Multilayer Piezoelectric Element]

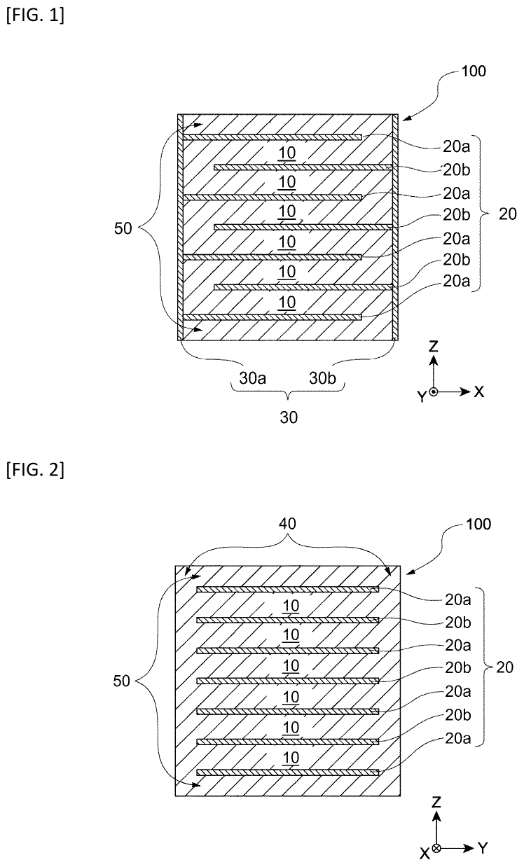

The multilayer piezoelectric element 100 pertaining to one aspect of the present invention (hereinafter also denoted simply as “this aspect”) comprises piezoelectric ceramic layers 10, internal electrodes 20 placed between the piezoelectric ceramic layers 10, and connection conductors 30 electrically connecting every other layer of the internal electrodes 20, according to its cross-sectional views shown schematically in FIG. 1 and FIG. 2. It should be noted that, of the internal electrodes 20 shown in FIG. 1 and FIG. 2 and connection conductors 30 shown in FIG. 1, those denoted by the same alphabet (“a” or “b”) have the same polarity (“+” or “−”). Also, while the multilayer piezoelectric element 100 shown in FIG. 1 has the connection conductors 30 formed on its surface, the connection conductors 30 may also be formed in the interior of the multilayer piezoelectric element 100 in a manner passing through the piezoelectric ceramic layers 10.

This aspect is such that side margin parts 40 positioned between the two side faces in the Y-axis direction and the internal electrodes 20, and cover parts 50 positioned at the top and bottom faces in the Z-axis direction, may also be formed, as shown in FIG. 2. In addition, this aspect may also be such that terminal electrodes (not illustrated) that electrically connect the connection conductors 30 and a drive circuit are formed on the surface, or the connection conductors 30 formed on the surface also serve as terminal electrodes.

Each part constituting the multilayer piezoelectric element 100 is described in detail below.

### (Piezoelectric Ceramic Layers)

The primary component of the piezoelectric ceramic layers 10 is an alkali niobate having a perovskite structure.

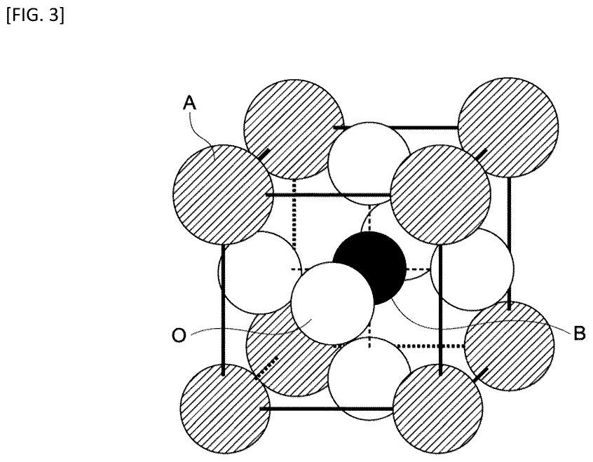

The alkali niobate, being the primary component, is an oxide having a perovskite structure that contains at least one type of alkali metal element selected from the group that consists of lithium (Li), sodium (Na), and potassium (K), along with niobium (Nb), as its constituent elements. Here, a perovskite structure represents a crystal structure having A sites positioned at the apexes of the unit lattice, O sites positioned at the face centers of the unit lattice, and a B site positioned inside the octahedron whose apexes correspond to the O sites, as shown in FIG. 3. In the case of the alkali niobate in this embodiment, its alkali metal ions are positioned at the A sites, niobium ion, at the B site, and oxide ion, at the O sites, respectively. Apart from this, each site may also contain various ions other than those mentioned above.

Here, the following steps are followed to confirm that the primary component of the piezoelectric ceramic layers 10 is an alkali niobate having a perovskite structure.

First, the piezoelectric ceramic layer 10 exposed at the surface of the multilayer piezoelectric element 100, or a powder obtained by pulverizing the multilayer piezoelectric element 100, is measured with an X-ray diffraction (XRD) device using Cu-Kα rays to measure its diffraction line profiles. The method for exposing the piezoelectric ceramic layers 10 at the surface of the multilayer piezoelectric element 100 is not specifically limited, and a method of cutting or grinding the piezoelectric element, or the like, can be adopted. Also, the means for pulverizing the multilayer piezoelectric element 100 is not specifically limited, either, and a hand mill (mortar/pestle), or the like, can be utilized.

Next, if the percentages, to the strongest diffraction line intensity in the profile derived from a perovskite structure, of the strongest diffraction line intensities in the diffraction line profiles derived from other structures, among the obtained diffraction line profiles, are 10% or lower, it is determined that the primary component of the piezoelectric ceramic layers 10 is a compound having a perovskite structure. Here, the XRD measurement, if performed on a pulverized powder of the multilayer piezoelectric element 100, also detects peaks due to the metals constituting the internal electrodes 20 and accordingly they must be excluded when conducting the aforementioned comparison of diffraction line intensities.

Next, the piezoelectric ceramic layers 10 whose primary component has been determined to be a compound having a perovskite structure, or powder prepared therefrom, are/is measured for the ratio of each element contained using a high-frequency inductively coupled plasma (ICP) optical emission spectrometer, ion chromatograph system, or X-ray fluorescence (XRF) analyzer. If, as a result of the measurement, both the total content of alkali metal elements and niobium content expressed in % by mol (or % by atom) are greater than the contents of other elements, it is determined that the primary component, or specifically compound having a perovskite structure, is an alkali niobate.

The piezoelectric ceramic layers 10 contain at least one type of alkali earth metal element selected from the group that consists of calcium (Ca), strontium (Sr), and barium (Ba), along with silver (Ag). As a result, the piezoelectric ceramic layers 10 become dense, having small sintered-grain diameters, and thereby manifest excellent piezoelectricity. While the content of alkali earth metal elements and that of silver in the piezoelectric ceramic layers 10 are not limited, alkali earth metal elements account for preferably over 0.2% by mol, or more preferably 0.3% by mol or more, or yet more preferably 0.5% by mol or more, when the content of the elements (often in ion state in reality) within the B site of the alkali niobate being the primary element represents 100% by mol, from the viewpoint of making the multilayer piezoelectric element one offering excellent piezoelectricity. Also, for the same reason, silver accounts for preferably over 0.5% by mol, or more preferably 0.7% by mol or more, or yet more preferably 1.0% by mol or more, relative to the elements within the B site representing 100% by mol. On the other hand, from the viewpoint of further improving the electrical insulating property of the piezoelectric ceramic layers 10 to allow for use under high electric fields, while also extending the element's service life, the total content of the alkali earth metal elements is preferably 5.0% by mol or lower, or more preferably 3.0% by mol or lower, or yet more preferably 1.0% by mol or lower. Also, for the same reason, the content of the silver is preferably 5.0% by mol or lower, or more preferably 4.0% by mol or lower, or yet more preferably 3.0% by mol or lower. Additionally, for the reasons mentioned above, the total content of the alkali earth metal elements and content of the silver are such that preferably the total content of alkali earth metal elements is over 0.2% by mol but no higher than 5.0% by mol and the content of silver is over 0.5% by mol but no higher than 5.0% by mol, or more preferably the total content of alkali earth metal elements is 0.3% by mol or higher but no higher than 3.0% by mol and the content of silver is 0.7% by mol or higher but no higher than 4.0% by mol, or yet more preferably the total content of alkali earth metal elements is 0.5% by mol or higher but no higher than 1.0% by mol and the content of silver is 1.0% by mol or higher but no higher than 3.0% by mol, relative to the elements within the B site representing 100% by mol.

The alkali earth metal elements and silver contained in the piezoelectric ceramic layers 10 can be mixed into a solid solution at the A sites of the alkali niobate being the primary component. Also, if the piezoelectric ceramic layers 10 contain Ta and Sb, these elements can be mixed into a solid solution at the B sites of the alkali niobate. When such elements exist in a solid solution state within the alkali niobate, the alkali niobate containing the elements in a solid solution state becomes the primary component of the piezoelectric ceramic layers 10.

Preferably the primary component is expressed by composition formula (1) below from the viewpoint of manifesting excellent piezoelectric properties, and also from the viewpoint of obtaining an element that demonstrates a long service life when used under high electric fields:

(AgᵤM2ᵥ(K_{1-w-x}Na_{w}Liₓ)₁₋ᵤ₋ᵥ)ₐ(Sb_{y}Ta_{z}Nb_{1-y-z})O₃ (1)
provided that M2 in the formula represents at least one type of alkali earth metal element selected from the group that consists of calcium (Ca), strontium (Sr), and barium (Ba). Also, u, v, w, x, y, z, and a are each a numerical value satisfying each of the inequalities expressed by 0.005<u≤0.05, 0.002<v≤0.05, 0.007<u+v≤0.1, 0≤w≤1, 0.02<x≤0.1, 0.02<w+x≤1, 0≤y≤0.1, 0≤z≤0.4, and 1<a≤1.1.

Here, the following steps are followed to confirm that the alkali niobate is one expressed by composition formula (1) above.

First, the piezoelectric ceramic layers 10 or powder prepared therefrom, whose primary component has been confirmed by the aforementioned steps as being an alkali niobate having a perovskite structure, are/is measured for the contents of silver (Ag), calcium (Ca), strontium (Sr), barium (Ba), potassium (K), sodium (Na), lithium (Li), antimony (Sb), tantalum (Ta), and niobium (Nb) using a high-frequency inductively coupled plasma (ICP) optical emission spectrometer, ion chromatograph system, or X-ray fluorescence (XRF) analyzer. It should be noted that, if a powder prepared from the piezoelectric ceramic layers 10 is to be the measurement target, a powder not containing the internal electrode components should be used in order to eliminate the effects of silver contained in the internal electrodes.

Next, the total number of moles of antimony, tantalum, and niobium is calculated, and the percentage of the number of moles of each of the elements mentioned above, to this total, is calculated.

Then, if the obtained percentage of each of the elements mentioned above is within the range of composition formula (1) above, the alkali niobate is determined to be one expressed by composition formula (1) above.

The piezoelectric ceramic layers 10 contain lithium by an amount corresponding to 0.1% by mol or more but no more than 2.0% by mol, and silicon by an amount corresponding to 1.5% by mol or more but no more than 4.0% by mol, relative to the aforementioned primary component representing 100% by mol, in a manner that the ratio by mol of the lithium to the silicon, or Li/Si, becomes 0.025 or higher but under 0.40. This allows the multilayer piezoelectric element 100 to have both a long service life and excellent piezoelectric properties even when fired at or below the heat resistance temperature of the internal electrodes 20 described below. From the viewpoint of achieving long service life and excellent piezoelectric properties of the multilayer piezoelectric element 100 at higher levels, the content of the lithium is preferably 0.2% by mol or higher but no higher than 1.8% by mol, or more preferably 0.3% by mol or higher but no higher than 1.5% by mol, or yet more preferably 0.4% by mol or higher but no higher than 1.2% by mol, relative to the aforementioned primary component representing 100% by mol. Also, for the same reason, the content of the silicon is preferably 1.8% by mol or higher but no higher than 3.9% by mol, or more preferably 2.0% by mol or higher but no higher than 3.8% by mol, or yet more preferably 2.2% by mol or higher but no higher than 3.7% by mol, relative to the aforementioned primary component representing 100% by mol. Additionally, for the same reason, the Li/Si is preferably 0.05 or higher but no higher than 0.38, or more preferably 0.08 or higher but no higher than 0.36, or yet more preferably 0.10 or higher but no higher than 0.34. It should be noted that, while Li is also a constituent element of the aforementioned primary component, the amount of Li explained here does not include the Li in the primary component. The amount of Li contained in the piezoelectric ceramic layers 10 but not constituting the primary component is calculated as the balance of the total amount of Li obtained as a result of compositional analysis under the method for determining the composition formula of the alkali niobate as mentioned above, less the amount of Li that can exist in the alkali niobate as a solid solution.

The piezoelectric ceramic layers 10 are such that, when an X-ray diffraction measurement is performed using Cu-Kα rays, wherein the strongest diffraction line intensity at 10.00°≤2θ≤50.00° is referred to as Iₘₐₓ, the strongest diffraction line intensity at 26.50°≤2θ≤27.50° is referred to as I_{L2S}, and the average value of diffraction line intensity at 27.50°≤2θ≤29.00° is referred to as IBG, R₁=(I_{L2S}−I_{BG})/(Iₘₐₓ−I_{BG})×100≥0.20 is satisfied. This allows the multilayer piezoelectric element 100 to have both a long service life and excellent piezoelectric properties. The aforementioned Iₘₐₓ, as it pertains to the piezoelectric ceramic layers 10 whose primary component is an alkali niobate having a perovskite structure, corresponds to the main peak intensity of the alkali niobate being the primary component. Also, the aforementioned I_{L2S} corresponds to the main peak intensity of the Li₂SiO₃, while the aforementioned IBG corresponds to the background X-ray intensity. This means that the greater the value of the aforementioned R₁, the higher the percentage of the Li₂SiO₃ relative to the primary component. Accordingly, it is estimated that a content of Li₂SiO₃ equal to or higher than a set percentage relative to the primary component helps extend the service life, and improve the piezoelectric properties, of the multilayer piezoelectric element 100. From the viewpoint of achieving long service life and excellent piezoelectric properties of the multilayer piezoelectric element 100 at higher levels, the value of the aforementioned R₁ is preferably 0.23 or greater, or more preferably 0.24 or greater, or yet more preferably 0.25 or greater. The upper-limit value of the aforementioned R₁, while not specifically limited so long as it is one obtained at the aforementioned contents of lithium and silicon, is preferably 0.60 or lower, or more preferably 0.50 or lower, or yet or preferably 0.40 or lower. For the aforementioned reason, the value of the R₁ is preferably 0.23 or greater but no greater than 0.60, or more preferably 0.24 or greater but no greater than 0.50, or yet more preferably 0.25 or greater but no greater than 0.40.

The piezoelectric ceramic layers 10 are such that, when an X-ray diffraction measurement is performed using Cu-Kα rays, wherein the strongest diffraction line intensity at 25.70°≤2θ≤26.00° is referred to as I_{L3N}, preferably this and the aforementioned Iₘₐₓ and IBG satisfy the relationship of R₂=(I_{L3N}−I_{BG})/(Iₘₐₓ−I_{GB})×100≤0.55 among them. This allows the multilayer piezoelectric element 100 to achieve both a long service life and excellent piezoelectric properties at higher levels. The aforementioned I_{L3N} corresponds to the main peak intensity of the Li₃NbO₄, and the value of the aforementioned R₂ matches the percentage of the Li₃NbO₄ relative to the alkali niobate being the primary component. This means that the smaller the value of the aforementioned R₂, the lower the percentage of the Li₃NbO₄ relative to the primary component becomes. Since Li₃NbO₄ is a compound having conductivity, it is estimated that a lower percentage of it helps extend the service life, and improve the piezoelectric properties, of the multilayer piezoelectric element 100. From the viewpoint of further extending the service life of the multilayer piezoelectric element 100 as well as achieving superior piezoelectric properties, the value of the aforementioned R₂ is preferably 0.40 or lower, or more preferably 0.20 or lower. The lower the lower-limit value of the R₂, the better; however, this value will reach at least 0.05 or so in a measurement using a general-purpose X-ray diffraction device, even when the I_{L3N} is not recognized as a peak.

The X-ray diffraction measurement through which to obtain each of the aforementioned peak diffraction line intensities can be performed in the same manner as the aforementioned X-ray diffraction measurement performed when confirming whether or not the primary component of the piezoelectric ceramic layers 10 is an alkali niobate having a perovskite structure.

The piezoelectric ceramic layers 10 may contain manganese (Mn) in addition to the aforementioned components. This way, the electrical insulating property of the piezoelectric ceramic layers 10 will improve and a multilayer piezoelectric element 100 demonstrating a long service life can be obtained. The content of manganese is not specifically limited, but from the viewpoint of achieving excellent electrical insulating property, it is preferably 0.2% by mol or higher, or more preferably 0.3% by mol or higher, or yet more preferably 0.5% by mol or higher, when the alkali niobate being the primary component represents 100% by mol. From the viewpoint of making the piezoelectric ceramic layers 10 excellent in piezoelectric properties, on the other hand, the content of manganese is preferably 2.0% by mol or lower, or more preferably 1.5% by mol or lower, or yet more preferably 1.0% by mol or lower, relative to the aforementioned primary component representing 100% by mol. Also, for the aforementioned reasons, the content of manganese is preferably 0.2% by mol or higher but no higher than 2.0% by mol, or more preferably 0.3% by mol or higher but no higher than 1.5% by mol, or yet more preferably 0.5% by mol or higher but no higher than 1.0% by mol, relative to the aforementioned primary component representing 100% by mol.

Besides these components, the piezoelectric ceramic layers 10 may contain, as necessary, at least one element selected from Sc, Ti, V, Cr, Fe, Co, Ni, Cu, and Zn representing the first transition series of the elements. When these elements are contained by appropriate amounts, it becomes possible to adjust the firing temperature, control particle growth, and extend service life under high electric fields, of the multilayer piezoelectric element 100.

Also, the piezoelectric ceramic layers 10 may contain, as necessary, at least one element selected from Y, Zr, Mo, Ru, Rh, and Pd representing the second transition series of the elements. When these elements are contained by appropriate amounts, it becomes possible to adjust the firing temperature, control particle growth, and extend service life under high electric fields, of the multilayer piezoelectric element 100.

In addition, the piezoelectric ceramic layers 10 may contain, as necessary, at least one element selected from La, Ce, Pr, Nd, Sm, Eu, Gd, Tb, Dy, Ho, Er, Tm, Yb, Lu, Hf, W, Re, Os, Ir, Pt, and Au representing the third transition series of the elements. When these elements are contained by appropriate amounts, it becomes possible to adjust the firing temperature, control particle growth, and extend service life under high electric fields, of the multilayer piezoelectric element 100.

Needless to say, in this embodiment, multiple types of elements in the first transition series of the elements, second transition series of the elements, and third transition series of the elements can be contained in the piezoelectric ceramic layers 10.

### (Internal Electrodes)

The internal electrodes 20 are formed by a metal whose silver content is 80% by mass or higher. By setting the silver content to 80% by mass or higher, the use amounts of platinum, palladium, and other expensive metals can be reduced to keep the manufacturing cost of the element low. Also, it increases the percentage of silver having excellent conductivity, which in turn decreases electrical resistivity of the internal electrodes 20 and reduces their electrical loss when used as a piezoelectric element. Examples of the metal whose silver content is 80% by mass or higher include silver-palladium alloys and silver. The content of silver in the metal that constitutes the internal electrodes 20 is preferably 85% by mass or higher, or more preferably 90% by mass or higher, or yet more preferably 95% by mass or higher.

The content of silver in the internal electrodes 20 can be confirmed by performing an element analysis of the internal electrodes 20 using any of various types of measuring equipment, and then calculating the percentage by mass of silver relative to all detected elements. Examples of the measuring equipment used include energy dispersive X-ray spectrometers (EDS) or wavelength dispersive X-ray spectrometers (WDS), electron probe micro-analyzers (EPMA), and laser ablation inductively coupled plasma mass spectrometers (LA-ICP-MS), installed either on scanning electron microscopes (SEM) or transmission electron microscopes (TEM), and the like.

### (Connection Conductors)

The connection conductors 30 electrically connect every other layer of the internal electrodes 20. The material of the connection conductors 30, if formed on the surface of the multilayer piezoelectric element 100, is not specifically limited so long as it has high conductivity and is physically and chemically stable under the polarizing conditions described below and in the use environment of the element. Examples include silver (Ag), copper (Cu), gold (Au), platinum (Pt), palladium (Pd), and nickel (Ni), as well as alloys thereof, and the like. If, on the other hand, the connection conductors 30 are formed in the interior of the multilayer piezoelectric element 100 in a manner passing through the piezoelectric ceramic layers 10, preferably a metal whose silver content is 80% by mass or higher is used, as is the case with the internal electrodes 20 mentioned above.

### (Side Margin Parts and Cover Parts)

The side margin parts 40 and cover parts 50 function as protective parts for protecting the piezoelectric ceramic layers 10 and internal electrodes 20.

Preferably the side margin parts 40 and cover parts 50 are formed by a sintered body whose primary component is an alkali niobate, just like the piezoelectric ceramic layers 10, from the viewpoints of the shrinkage factor of the multilayer piezoelectric element 100 during firing, mitigation of internal stress in the multilayer piezoelectric element 100, and the like. However, the material with which to form the side margin parts 40 and cover parts 50 need not be one whose primary component is an alkali niobate so long as it is a material having high insulating property.

### (Terminal Electrodes)

The terminal electrodes have a function to electrically connect the connection conductors 30 and a drive circuit. Additionally, if formed on the piezoelectric ceramic layers 10, they also have a function to impress voltage thereon. The material of the terminal electrodes 30 is not specifically limited so long as it has high conductivity and is physically and chemically stable under the polarizing conditions and in the use environment of the element. Examples include silver (Ag), copper (Cu), gold (Au), platinum (Pt), palladium (Pd), and nickel (Ni), as well as alloys thereof, and the like.

### [Method for Manufacturing Multilayer Piezoelectric Ceramic]

The multilayer piezoelectric element pertaining to this aspect is manufactured, for example, through: preparing green sheets containing a powder of an alkali niobate having a perovskite structure, one type or multiple types of powders containing at least one alkali earth metal element selected from calcium, strontium, and barium, as well as specified amounts of the elements lithium and silicon, and a binder; placing on the green sheets a precursor to internal electrodes containing a metal whose silver content is 80% by mass or higher; stacking a specified number of the green sheets on which the metal paste has been printed and pressure-bonding them to obtain a formed green sheet; removing the binder from the formed green sheet, followed by firing, to obtain a multilayer piezoelectric ceramic; applying a conductor paste on the surfaces of the multilayer piezoelectric ceramic at which the internal electrodes are exposed, followed by baking, to form connection conductors and terminal electrodes; and impressing high voltage between the terminal electrodes to perform polarization treatment of the piezoelectric ceramic layers. Each operation is described in detail below.

### (Preparation of Alkali Niobate Powder)

The powder of an alkali niobate having a perovskite structure can be obtained, for example, by mixing at a desired ratio a powder of a compound containing at least one type of alkali metal element selected from lithium, sodium, and potassium, and a powder of a compound containing niobium, and then firing (calcining) the mixture. So that the final product, or specifically piezoelectric ceramic, will have desired properties, compounds containing elements other than alkali metals or niobium may also be compounded.

Examples of the compounds that are used as materials include lithium compounds such as lithium carbonate (Li₂CO₃) and lithium fluoride (LiF), sodium compounds such as sodium carbonate (Na₂CO₃) and sodium hydrogen carbonate (NaHCO₃), potassium compounds such as potassium carbonate (K₂CO₃) and potassium hydrogen carbonate (KHCO₃), as well as niobium compounds such as niobium pentoxide (Nb₂O₅). Also, the compounds that are often used despite being optional components include tantalum compounds such as tantalum pentoxide (Ta₂O₅), antimony compounds such as antimony trioxide (Sb₂O₃), and the like.

The method for mixing the material powders is not specifically limited so long as the powders will be mixed uniformly in a manner preventing mixing-in of impurities, and either dry mixing or wet mixing may be adopted. When adopting wet mixing using a ball mill as the mixing method, the powders should be agitated for 8 to 60 hours or so using a ball mill that uses partially stabilized zirconia (PSZ) balls along with ethanol or other organic solvent as a dispersion medium, followed by volatilization-drying of the organic solvent, for example.

The calcining conditions for the material mixed powder are not specifically limited so long as the aforementioned compound powders will react with one another to give a desired alkali niobate. An example is firing in atmosphere for 1 to 10 hours at a temperature of 700 to 1000° C. Although the calcined powder may be used directly in the manufacturing of piezoelectric ceramic, preferably it is crushed using a ball mill, stamp mill, or the like, from the viewpoint of increasing the ease of mixing with the alkali earth metal compounds and organic binders described below, and also from the viewpoint of obtaining smooth green sheets by way of a uniform slurry.

It should be noted that, if any commercial alkali niobate powder can be utilized, the subsequent operations may be performed on this powder without the aforementioned mixing and calcining of the material powders.

### (Production of Green Sheets)

The green sheets containing an alkali niobate powder, one type or multiple types of powders containing at least one alkali earth metal element selected from calcium, strontium, and barium, as well as specified amounts of the elements lithium and silicon, and a binder, are obtained, for example, by adding to the alkali niobate powder the one type or multiple types of powders containing at least one alkali earth metal element selected from calcium, strontium, and barium, as well as specified amounts of the elements lithium and silicon, and then mixing the obtained mixed powder with the binder and a dispersion medium to prepare a slurry, followed by forming of the slurry into a sheet shape.

Examples of the powders containing alkali earth metals include those containing calcium such as calcium carbonate (CaCO₃), calcium metasilicate (CaSiO₃), and calcium orthosilicate (Ca₂SiO₄), those containing strontium such as strontium carbonate (SrCO₃), and those containing barium such as barium carbonate (BaCO₃), respectively.

Examples of the powders containing lithium include lithium carbonate (Li₂CO₃), lithium fluoride (LiF), lithium metasilicate (Li₂SiO₃), and lithium orthosilicate (Li₄SiO₄).

Examples of the powders containing silicon include silicon dioxide (SiO₂), in addition to the aforementioned lithium metasilicate (Li₂SiO₃) and lithium orthosilicate (Li₄SiO₄).

For the binder, one that can retain the shape of the green sheets as described below, while allowing carbon, etc., to fully volatilize without remaining during the course of the firing and the binder removal treatment prior thereto, is used. Examples of the binders that can be used include polyvinyl alcohol-based, polyvinyl butyral-based, cellulose-based, urethane-based, and vinyl acetate-based binders. Although not specifically limited, either, the use amount of the binder, which will be removed in a subsequent process, is preferably minimized as much as possible within a range that achieves desired formability and shape retainability, from the viewpoint of reducing the material cost.

For the dispersion medium, one that does not cause the calcined powder and binder to aggregate, and can be removed easily through volatilization, etc., following the formation of green sheets as described below, is used. Examples of the dispersion media that can be used include water, alcohol-based solvents, and the like.

To the slurry, dispersants, plasticizers, thickening agents, and other components for adjusting the properties of the slurry may be added.

The method for mixing the mixed powder with the binder and dispersion medium is not specifically limited so long as the components will be mixed uniformly in a manner preventing mixing-in of impurities. Ball-mill mixing is an example.

Regarding the method for forming the prepared slurry into a sheet shape to obtain green sheets, the doctor blade method or other commonly used methods can be adopted.

### (Placement of Precursor to Internal Electrodes)

The placement of the precursor to internal electrodes on the green sheets can be implemented, for example, by printing on the green sheets an internal electrode paste containing a metal whose silver content is 80% by mass or higher. The internal electrode paste may have glass frit, or powders having the same compositional makeup as the alkali niobate powder contained in the green sheets, added to it in order to improve adhesion strength to the piezoelectric ceramic layers after firing.

When the internal electrode paste is printed on the green sheets, spaces that will become the side margin parts in the eventual multilayer piezoelectric element may be excluded from the printing.

### (Production of Formed Green Sheet)

The formed green sheet is obtained, for example, by stacking a specified number of green sheets on which the precursor to internal electrodes has been placed, and then pressure-bonding the green sheets together. The stacking and pressure-bonding should be performed according to commonly used methods, and a method of pressing, while heating, the stacked green sheets in the stacking direction in order to pressure-bond them thermally through action of the binder, or the like, can be adopted.

At the time of stacking and pressure-bonding, green sheets that will become the cover parts in the eventual multilayer piezoelectric element may be added in the two end parts in the stacking direction. In this case, the green sheets to be added may have the same compositional makeup as the green sheets on which the precursor to internal electrodes has been placed, or a different compositional makeup. From the viewpoint of achieving a uniform shrinkage factor during firing, preferably the compositional makeup of the green sheets to be added is the same as, or similar to, the aforementioned green sheets on which the precursor to internal electrodes has been placed.

### (Production of Multilayer Piezoelectric Ceramic)

The multilayer piezoelectric ceramic is obtained by firing the aforementioned formed green sheet. The binder may be removed from the formed green sheet prior to firing. In this case, the binder removal and firing may be performed successively using the same firing device. The conditions for binder removal and firing should be set as deemed appropriate in consideration of the volatilization temperature and content of the binder, sintering property of the alkali niobate, heat resistance of the metals contained in the internal electrode paste, and the like. Examples of the conditions under which to remove the binder include 5 to 20 hours at a temperature of 300 to 500° C. in atmosphere. Also, examples of the firing conditions include 1 to 5 hours at 800 to 1100° C. in atmosphere. When multiple multilayer piezoelectric ceramics are to be obtained from one formed green sheet, the formed green sheet may be split into several blocks prior to firing.

The aforementioned firing produces sintered layers whose primary component is an alkali niobate, from the green sheets, while at the same time producing internal electrodes from the precursor to internal electrodes. At this time, silver diffuses to the sintered layers from the internal electrodes to make the sintered layers silver-containing. Then, an interaction between this silver, and the alkali earth metal elements added during the production of the green sheets, makes the obtained sintered layer dense, being formed by fine sintered grains.

Also, the aforementioned firing causes the lithium and silicon that were added during production of the green sheets, as well as the lithium being a component of the alkali niobate, to react together to produce Li₂SiO₃.

### (Formation of Connection Conductors and Terminal Electrodes)

The connection conductors and terminal electrodes can be formed, for example, by applying a conductor paste on the surface of the obtained multilayer piezoelectric ceramic, followed by baking.

### (Polarization Treatment)

The polarization treatment is applied by impressing high voltage between the aforementioned terminal electrodes. The conditions for polarization treatment are not specifically limited so long as the orientations of spontaneous polarization in the respective piezoelectric ceramic layers can be aligned without causing cracks in, or other damage to, the multilayer piezoelectric ceramic. An example is impressing an electric field of 2 to 6 kV/mm at a temperature of 100 to 150° C.

### EXAMPLES

The present invention is explained in greater detail below using examples; however, the present invention is not limited to these examples.

### Example 1

As a powder of an alkali niobate having a perovskite structure, a calcined powder expressed by the composition formula Li_{0.06}Na_{0.52}K_{0.42}NbO₃ was prepared. To this calcined powder representing 100% by mol, 0.6% by mol of BaCO₃, 0.4% by mol of Li₂CO₃, 2.5% by mol of SiO₂, 0.8% by mol of MnO, and a polyvinyl butyral-based binder, were each added and mixed together in a wet ball mill. The obtained mixed slurry was shaped using a doctor blade to obtain green sheets of 80 μm in thickness. On these green sheets, an Ag—Pd alloy paste (Ag/Pd ratio by mass=9/1) was screen-printed to form electrode patterns, after which 11 layers of the green sheets were stacked and pressure-bonded, under heating, by pressing them with a pressure of approx. 50 MPa, to obtain a laminate body. This laminate body was cut into individual pieces and then given a binder removal treatment in atmosphere, and subsequently fired for 2 hours at 970° C. in atmosphere, to obtain a fired body (multilayer piezoelectric ceramic). A conductive paste containing Ag was applied on the surface of this fired body and then baked by raising the temperature to 600° C., to form a pair of connection conductors and a pair of terminal electrodes. Lastly, an electric field of 3.0 kV/mm was impressed for 3 minutes between the pair of terminal electrodes in a thermostatic chamber set to 100° C. to perform polarization treatment, and the multilayer piezoelectric element pertaining to Example 1 was obtained as a result.

### Examples 2 and 3

The multilayer piezoelectric elements pertaining to Examples 2 and 3 were each obtained in the same manner as in Example 1, except that the additive amounts of Li₂CO₃ and SiO₂ relative to 100% by mol of the calcined powder were changed to 0.55% by mol of Li₂CO₃ and 3.5% by mol of SiO₂ (Example 2), and to 0.2% by mol of Li₂CO₃ and 2.5% by mol of SiO₂ (Example 3), respectively.

### Comparative Example 1

The multilayer piezoelectric element pertaining to Comparative Example 1 was obtained in the same manner as in Example 1, except that the additive amounts of Li₂CO₃ and SiO₂ relative to 100% by mol of the calcined powder were changed to 0.65% by mol of Li₂CO₃ and 1.3% by mol of SiO₂, and that the firing temperature was changed to 990° C.

### Comparative Examples 2 to 4

The multilayer piezoelectric elements pertaining to Comparative Examples 2 to 4 were each obtained in the same manner as in Comparative Example 1, except that the additive amounts of Li₂CO₃ and SiO₂ relative to 100% by mol of the calcined powder were changed to 0.65% by mol of Li₂CO₃ and 0.8% by mol of SiO₂ (Comparative Example 2), that Li₂CO₃ was not added and only 2.5% by mol of SiO₂ was added (Comparative Example 3), and that the additive amounts were changed to 1.0% by mol of Li₂CO₃ and 2.5% by mol of SiO₂ (Comparative Example 4), respectively.

The percentages by mol of lithium and silicon relative to the calcined powder, and firing temperature, in each of the Examples and Comparative Examples described above, are shown in Table 1, respectively.

### Evaluations

[Calculation of R₁ and R₂]

In each of the Examples and Comparative Examples, the fired body prior to forming of connection conductors and terminal electrodes was pulverized together with the internal electrodes into a powder, and the powder was measured by X-ray diffraction using Cu-Kα ray. The measurement was performed in a range of 100≤2θ≤500 at 0.020 intervals and a scan speed of 2°/min based on an accelerating voltage of 40 kV and current value of 40 mA. As a result of the measurement, the powders prepared from the fired bodies pertaining to the Examples and fired bodies pertaining to Comparative Examples 1, 3, and 4 showed peaks in the range of 26.50°≤2θ≤27.500 besides the peak due to the alkali niobate being the primary component. By contrast, the powder prepared from the fired body pertaining to Comparative Example 2 did not show such peaks. Also, the powders prepared from the fired bodies pertaining to Example 1, Comparative Examples 1, 2, and 4 also showed peaks in the range of 25.70°≤2θ≤26.00°, while the powders prepared from Examples 2, 3, and Comparative Example 3 did not show such peaks. From the measurement results, R₁ and R₂ were calculated based on the calculation formula described above. The values of R₁ and R₂ obtained with respect to each fired body are shown in Table 1, respectively.

### [Measurement of Element Distribution in Piezoelectric Ceramic Layers]

In each of the Examples, the fired body prior to forming of connection conductors and terminal electrodes was cut along a plane perpendicular to the piezoelectric ceramic layers and internal electrodes, and the piezoelectric ceramic layers in the exposed cross-section were measured for element distribution by means of ToF-SIMS. The result shows that, at the locations where lithium was detected at high concentrations, the silicon concentration was also high. From this result, and also from the aforementioned results of X-ray diffraction measurement, it can be argued that Li₂SiO₃ is present in the piezoelectric ceramic layers in the fired body pertaining to each of the Examples.

### [Measurement of Change in Electrical Insulating Property Over Time (Average Service Life)]

Each obtained multilayer piezoelectric element was placed in a thermostatic chamber set to 100° C. and a direct-current electric field of 8 kV/mm was impressed between the external electrodes, to measure the time it would take for the value of the current flowing between the external electrodes to reach 1 mA or higher. Then, the average value of this time over 10 units of the element was taken as the average service life. The average service life obtained for each element is shown in Table 1 as a ratio to the average service life of the multilayer piezoelectric element pertaining to Comparative Example 1 representing 100.

### [Evaluation of Piezoelectric Properties]

The piezoelectric properties of each obtained multilayer piezoelectric element were evaluated by its displacement performance d*₃₃ (pm/V). First, monopolar triangle waves producing the maximum electric field of 6 kV/mm at approx. 100 Hz were input to the multilayer piezoelectric ceramic and the resulting displacement magnitude of the multilayer piezoelectric element was measured using a laser doppler displacement meter. Then, the obtained displacement magnitude of the multilayer piezoelectric element was divided by the maximum voltage calculated from the thickness (distance between the electrodes) and maximum electric field of the piezoelectric ceramic layers, and also by the number of the piezoelectric ceramic layers constituting the multilayer piezoelectric element, to calculate the displacement performance d*₃₃ per unit voltage in one piezoelectric ceramic layer. The displacement performance d*₃₃ obtained for each element is shown in Table 1 as a ratio to the displacement performance d*₃₃ of the multilayer piezoelectric element pertaining to Comparative Example 1 representing 100.

TABLE 1

| | | | | Firing | | | | |
|---|---|---|---|---|---|---|---|---|
| | Li | Si | | temperature | | | Average | Piezoelectric |
| | [mol %]*¹ | [mol %]*¹ | Li/Si | [° C.] | R₁ | R₂ | service life*² | properties*² |
| Example 1 | 0.8 | 2.5 | 0.32 | 970 | 0.26 | 0.17 | 223 | 98 |
| Example 2 | 1.1 | 3.5 | 0.31 | 970 | 0.30 | 0.05 | 234 | 97 |
| Example 3 | 0.4 | 2.5 | 0.16 | 970 | 0.20 | 0.07 | 162 | 97 |
| Comparative | 1.3 | 1.3 | 1.00 | 990 | 0.13 | 0.58 | 100 | 100 |
| Example | | | | | | | | |
| 1 | | | | | | | | |
| Comparative | 1.3 | 0.8 | 1.63 | 990 | 0.08 | 0.67 | 61 | 91 |
| Example | | | | | | | | |
| 2 | | | | | | | | |
| Comparative | 0 | 2.5 | 0 | 990 | 0.18 | 0.05 | 78 | 92 |
| Example | | | | | | | | |
| 3 | | | | | | | | |
| Comparative | 2 | 2.5 | 0.80 | 990 | 0.27 | 0.62 | 137 | 95 |
| Example | | | | | | | | |
| 4 | | | | | | | | |

*¹Percentage when the calcined powder represents 100% by mol
*²Relative value when Comparative Example 1 represents 100

From the above results, it can be argued that a multilayer piezoelectric element achieving both long service life and excellent piezoelectric properties, despite being fired at low temperatures, can be obtained when its piezoelectric ceramic layers whose primary component is an alkali niobate contains alkali earth metal elements and silver, specific amounts of lithium and silicon, and a specified amount of Li₂SiO₃.

### Industrial Field of Application

According to the present invention, a multilayer piezoelectric element achieving both long service life and excellent piezoelectric specificity, which uses a piezoelectric ceramic whose primary component is an alkali niobate, can be provided at low cost. Such multilayer piezoelectric element does not include lead in its constituents and can also be used for a long period of time, and therefore proves useful in that burdens on the environment can be reduced throughout its life cycle. Additionally, the multilayer piezoelectric element also proves useful in that the high content percentage of silver in the internal electrodes lowers the electrical resistivity of the element, allowing any electrical loss to be reduced during use.

### DESCRIPTION OF THE SYMBOLS

100 Multilayer piezoelectric element
10 Piezoelectric ceramic layer
20, 20a, 20b Internal electrode
30, 30a, 30b Connection conductor
40 Side margin part
50 Cover part

1. A multilayer piezoelectric element comprising:
multiple piezoelectric ceramic layers, wherein:
a primary component constitutes a perovskite structure of an alkali niobate;
at least one of alkali earth metal element selected from calcium, strontium, and barium, as well as silver, are contained;
lithium by an amount corresponding to 0.10% by mol or more but no more than 2.0% by mol, and silicon by an amount corresponding to 1.5% by mol or more but no more than 4.0% by mol, relative to the primary component representing 100% by mol, are contained, other than those contained in the primary component, in a manner that a ratio by mol of the lithium to the silicon, or Li/Si, becomes 0.025 or higher but under 0.40; and
when an X-ray diffraction measurement is performed using Cu-Kα rays, wherein a strongest diffraction line intensity at 10.000≤2θ≤50.00° is referred to as Iₘₐₓ, a strongest diffraction line intensity at 26.50°≤2θ≤27.50° is referred to as I_{L2S}, and an average value of diffraction line intensity at 27.50°≤2θ≤29.00° is referred to as IBG, R₁=(I_{L2S}−I_{BG})/(Iₘₐₓ−I_{BG})×100≥0.20 is satisfied; and
internal electrodes that are:
placed between the multiple piezoelectric ceramic layers, respectively; and
formed by a metal whose silver content is 80% by mass or higher.

2. The multilayer piezoelectric element according to claim 1, wherein the alkali niobate is expressed by a composition formula below: 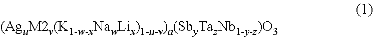
(provided that M2 in the formula represents at least one type of alkali earth metal selected from a group that consists of calcium (Ca), strontium (Sr), and barium (Ba); also, u, v, w, x, y, z, and a are each a numerical value satisfying each of inequalities expressed by 0.005<u≤0.05, 0.002<v≤0.05, 0.007<u+v≤0.1, 0≤w≤1, 0.02<x≤0.1, 0.02<w+x≤1, 0≤y≤0.1, 0≤z≤0.4, and 1<a≤1.1).

3. The multilayer piezoelectric element according to claim 1, wherein the piezoelectric ceramic layers are such that, when the X-ray diffraction measurement is performed using Cu-Kα rays, wherein a strongest diffraction line intensity at 25.70°≤2θ≤26.00° is referred to as I_{L3N}, R₂=(I_{L3N}−I_{BG})/(Iₘₐₓ−I_{GB})×100≤0.55 is satisfied.

4. The multilayer piezoelectric element according to claim 2, wherein the piezoelectric ceramic layers are such that, when the X-ray diffraction measurement is performed using Cu-Kα rays, wherein a strongest diffraction line intensity at 25.70≤2θ≤26.00° is referred to as I_{L3N}, R₂=(I_{L3N}−I_{BG})/(Iₘₐₓ−I_{GB})×100≤0.55 is satisfied.
